(19) United States
(12) Patent Application Publication
(10) Pub. No.: US 2002/0105317 A1
(43) Pub. Date: Aug. 8, 2002

(54) Device for obtaining the power of the direct current

(76) Inventor: Jack Lin, Chong Ho City (TW)

Correspondence Address: Jack Lin, 6F, No. 440-2, Gin PIn Road, Chong Ho City, Taipei Hsien, 235, TW

(21) Appl. No.: 09/780,050

(22) Filed: Feb. 8, 2001

(51) Int. Cl. G01R 19/30

(52) U.S. Cl. 324/103 P

(57) ABSTRACT

A device is used for detecting and obtaining the power of the direct current (DC) from a DC and VDC of an electric facility, and includes an amplifying device for amplifying the DC and VDC values from the electric facility. A converting device may be used to convert the DC and VDC values into digital values and to supply the digital DC and VDC values into a calculator or a processor device which may calculate from the DC and VDC values into a power value which may be displayed in a displayer device. The user may know how much power has been consumed for each electric facility.

### BACKGROUND OF THE INVENTION

1. Field of the Invention

The present invention relates to a device, and more particularly to a device for detecting and obtaining the power of the direct current (DC).

2. Description of the Prior Art

Most of the typical household electric facilities are powered or energized by the alternation current (AC). The families may only know how much electricity has been consumed per month. People may not know exactly how much power has been consumed by each of the electric facilities, such as the computers, the electric cooking devices, the air conditioners, the refrigerators, the televisions, etc. People also may not know exactly how much power has been consumed by the electric facilities that are powered or energized by the direct current (DC), such as the boats, the vehicles, particularly the vehicles powered by the electrical energy. In addition, people may not know which of the electric facilities consume less electric energy and thus may not choose or select and purchase the electric facilities that consume less electric energy.

The present invention has arisen to mitigate and/or obviate the afore-described disadvantages of the conventional electric facilities.

### SUMMARY OF THE INVENTION

The primary objective of the present invention is to provide a device for detecting and obtaining the power of the direct current and for allowing people to know how much power has been consumed by each of the electric facilities.

In accordance with one aspect of the invention, there is provided a device for detecting and obtaining the power of the direct current (DC) from a DC and VDC of an electric facility, the device comprising means for amplifying the DC and VDC values from the electric facility, means for calculating a power value from the DC and VDC values, and means for displaying the power value.

The amplifying means includes an amplifying device for amplifying the DC and VDC values. For example, the amplifying device includes two amplifiers for amplifying the DC and VDC values respectively.

A device is further provided for converting the DC and VDC values into digital values and includes a first zenor riode for providing a reference voltage signal, and a second zenor riode for converting the DC and VDC values into the digital values.

A device is further provided for encoding the digital DC and VDC values into encoded values and for supplying the encoded values to the displaying means.

Further objectives and advantages of the present invention will become apparent from a careful reading of a detailed description provided hereinbelow, with appropriate reference to accompanying drawings.

### BRIEF DESCRIPTION OF THE DRAWINGS

FIG. 1 is an electric circuit of a device for detecting and obtaining the power of the direct current in accordance with the present invention; and

FIGS. 2 and 3 are block diagrams illustrating the operation of the device for detecting and obtaining the power of the direct current.

### DETAILED DESCRIPTION OF THE PREFERRED EMBODIMENT

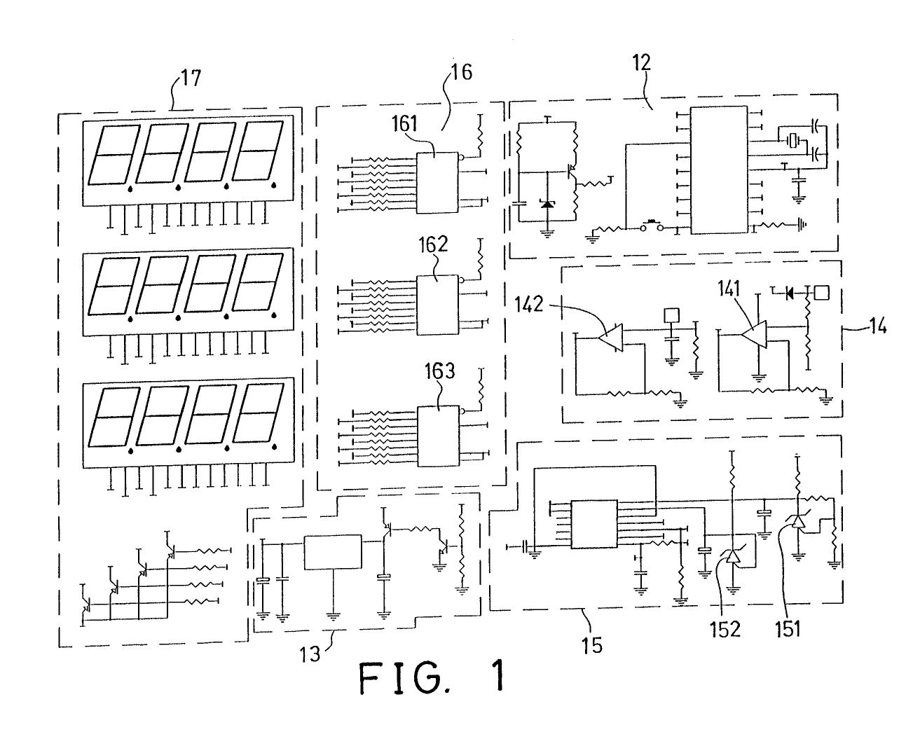

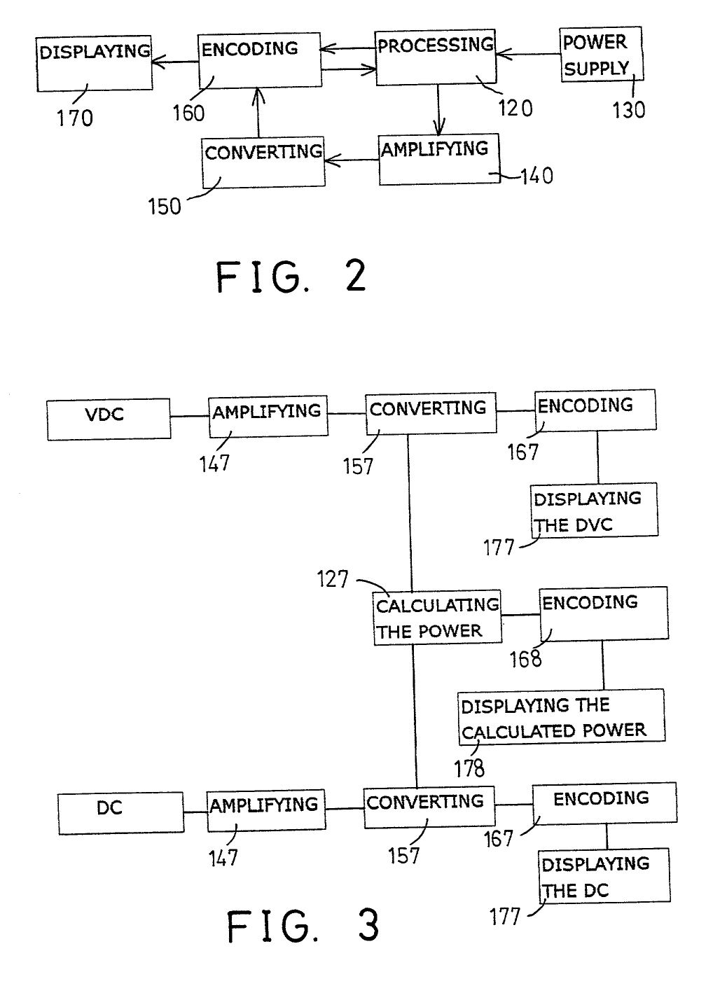

Referring to the drawings, and initially to FIGS. 1 and 2, a device in accordance with the present invention is provided for detecting and obtaining the power of the direct current (DC) and comprises a processor unit 12 for processing purposes 120, and a power circuit or a power supply unit 13 for supplying 130 the electric power to the processor unit 12. For example, the power supply unit 13 may be coupled to the household alternation current AC power supply and may convert the AC power into a DC power in order to energize the processor unit 12 and thus the device in accordance with the present invention.

An amplifying device 14, such as an operational amplifying device, may be coupled to the electric facility to be detected for receiving and obtaining and detecting the current of the DC and the voltage of the DC (VDC). The amplifying device 14 includes two amplifiers 141, 142 for amplifying the DC and the VDC of the electric facility 140 (FIG. 2), 147 (FIG. 3). The amplified DC and VDC are then supplied to an analog digital converter 15 which includes a zenor riode 152 for providing a reference voltage, and another zenor riode 151 for providing as a converting device to convert the analog DC and VDC signals into digital outputs or signals 150 (FIG. 2), 157 (FIG. 3).

An encoding device 16 includes three memory devices 161, 162, 163 for receiving and obtaining the digital signals from the analog digital converter 15 and for encoding (160 of FIG. 2, and 167 of FIG. 3) the digital signals into the signals for displaying purposes. The encoded signals from the encoding device 16 are then supplied into a displayer device 17 which may display (170, 177) the signals. As shown in FIG. 3, the digital signals from the analog digital converter 15 are also supplied into the processor unit 12 for calculating the DC and VDC values into the power of the DC which may also be encoded 168 by the encoding device 16 and displayed 178 by the displayer device 17. The displayer device 17 may be the light emitting diodes (LED) or may be the light crystal displayer (LCD)

The following equations may be used to obtain the power of DC (P):

(1) P=I×V; in which I is the current of DC, and the V is the VDC.

(2) V=I×R; in which R is the resistance.

(3) R=ρ×L/A; in which ρ is the coefficient of resistance, L is the length of the detected material, and A is the surface of the detected material.

(4) P=I×V=I×I×R=I²×ρ×L/A.

The processor unit 12 thus may be used to calculate and to obtain the power of the DC (PDC) which may be displayed in the displayer 17. The users may thus easily see and know the power consumed by each of the electric facilities, and may thus choose and select the electric facilities that consume less electric energy.

Accordingly, the device in accordance with the present invention may be used for detecting and obtaining the power of the direct current (DC) and for allowing people to know how much power has been consumed by each of the electric facilities.

Although this invention has been described with a certain degree of particularity, it is to be understood that the present disclosure has been made by way of example only and that numerous changes in the detailed construction and the combination and arrangement of parts may be resorted to without departing from the spirit and scope of the invention as hereinafter claimed.

I claim:

1. A device for detecting and obtaining the power of the direct current (DC) from a DC and VDC of an electric facility, said device comprising:
means for amplifying the DC and VDC values from the electric facility,
means for calculating a power value from the DC and VDC values, and
means for displaying the power value.

2. The device according to claim 1, wherein said amplifying means includes an amplifying device for amplifying the DC and VDC values.

3. The device according to claim 2, wherein said amplifying device includes two amplifiers for amplifying the DC and VDC values respectively.

4. The device according to claim 1 further comprising means for converting the DC and VDC values into digital values.

5. The device according to claim 4, wherein said converting means includes a first zenor riode for providing a reference voltage signal, and a second zenor riode for converting the DC and VDC values into the digital values.

6. The device according to claim 1 further comprising means for encoding the digital DC and VDC values into encoded values and for supplying the encoded values to said displaying means.
